(19) United States
(12) Patent Application Publication
(10) Pub. No.: US 2020/0157703 A1
(43) Pub. Date: May 21, 2020

(54) BELOW MELTING TEMPERATURE FORMATION OF HIGH-DENSITY POLYCRYSTALLINE SILICON

(71) Applicant: MOSSEY CREEK TECHNOLOGIES, Jefferson City, TN (US)

(72) Inventors: John Carberry, Jefferson City, TN (US); Robert Tesch, Phoenix, AZ (US); Tim Wilson, Lafayette, CA (US); Devin Roberts, Powell, TN (US)

(73) Assignee: MOSSEY CREEK TECHNOLOGIES, Jefferson City, TN (US)

(21) Appl. No.: 16/522,059

(22) Filed: Jul. 25, 2019

Related U.S. Application Data
(60) Provisional application No. 62/703,087, filed on Jul. 25, 2018.

(51) Int. Cl. C30B 1/02

(52) U.S. Cl. CPC C30B 1/023

(57) ABSTRACT

A method is described for the atmospheric pressure sintering of silicon to form high density polycrystalline silicon preforms that optionally may be annealed at higher temperatures to form wafers suitable for use in solar cells. The preforms are formed from nanometer scale, high surface area silicon that is sintered to form the near “full density” polycrystalline silicon preforms. Subsequent annealing of the preforms may be used to grow grains suitable for use as wafers for solar cells. The polycrystalline silicon may be used directly to form semiconductor structures other than wafers suitable for solar cells, such as to form electrodes, electrode surfaces, and thermoelectric devices.

### REFERENCE TO RELATED APPLICATIONS

This application claims the benefit of U.S. Provisional Application No. 62/703,087 entitled “Below Melting Temperature Formation of Fully Dense Silicon” filed Jul. 25, 2018, which is incorporated by reference.

### BACKGROUND

Photovoltaic cells, commonly known as solar cells, are known devices used for direct conversion of solar radiation into electrical energy. Generally, solar cells are fabricated on a semiconductor wafer or substrate using semiconductor processing techniques to form a p-n junction near a surface of the semiconductor substrate.

Solar radiation contacting the surface of the semiconductor substrate creates electron and hole pairs in the bulk of the substrate, which migrate to p-doped and n-doped regions in the substrate, thereby generating a voltage differential between the differently doped regions of the semiconductor substrate. The doped regions of the semiconductor substrate are coupled to a conductor on the solar cell to direct electrical current from the cell to an external circuit. Commonly, the n-type junction, such as provided by phosphorous doping, is on the surface of the semiconductor substrate, while the p-type junction, such as provided by boron doping, is within the body of the semiconductor substrate.

The use of solar cells in electrical energy production is attractive, in part due to the inexpensive nature of solar radiation used to fuel energy production in the solar cells. As concerns rise as to the environmental cost of carbon dioxide emissions with respect to global warming and the acidification of the seas, and as the fuel costs associated with more conventional means of electricity production can be expected to increase, demand for solar cells for electrical energy production also increases.

Conventional methods for the production of solar cells are labor intensive, energy intensive, and materials intensive. Conventional methods also have often resulted in the production of solar cells having relatively low efficiency and high electricity production costs even in view of the “free” nature of solar radiation. For use in solar cells, optimal silicon wafers preferably have approximately 156-micron square dimensions, are approximately 160-microns thick or less, and have single crystal silicon grains of 1 centimeter or more.

For example, in one conventional method of producing solar cells, a polycrystalline silicon material is used as the electricity producing, semiconductor substrate of the solar cell. In this method, polycrystalline silicon wafers are obtained by first placing and packing essentially pure lumps of silicon in a crucible. The crucible is then loaded into a vacuum furnace that has heating elements made of graphite. The vacuum furnace heats the silicon lumps in excess of 1414 degrees Centigrade, causing the lumps to melt. The melted silicon is then allowed to cool in the crucible to encourage the formation of a large silicon ingot including some polycrystalline crystal formations.

The time required to complete the heating and cooling cycles of the crucible including the silicon is often in the 45- to 60-hour range. Thus, the time associated with forming the polycrystalline silicon ingot can result in significant delays in the production process.

The crucible is commonly constructed of fused silica and, because of the processing temperature of the vacuum furnace, the fused silica forming the walls of the crucible partially converts to cristobalite during the melting of the lumps of silicon. Thus, the crucible is generally limited to a single use due to the degradation of its interior surface.

This melting process produces a polycrystalline silicon ingot having a large outer volume contaminated by impurities. Thus, to fabricate a useful wafer, the large outer volume of silicon contaminated by impurities is cut away and discarded following manufacture of the ingot. Thereafter, the remaining purer inner portion or “core” of the ingot is thin cut into discreet wafers using a wire saw. The wire saw causes additional material loss as it removes material between successively cut wafers and also limits the minimum thickness of the cut wafer to a thickness that can withstand the mechanical stress of the wire sawing process without breaking. The saw-cut polycrystalline silicon wafers are then laminated to a conductive layer to form a solar cell.

Such conventional methods of forming bulk polycrystalline silicon have been unsuccessful for multiple reasons. The fundamental problem is that if the silicon is heated to melting temperatures in the 1700 degrees Celsius range as often required to completely liquefy the silicon, the desired polycrystalline silicon only forms at the center of the mass—thus producing a very low yield due to the relatively large outer, contaminated volume.

Another conventional method used in making the silicon substrates for solar cells is the Czochralski process (CZ). In the CZ process high-purity, semiconductor-grade silicon is melted in a crucible at about 1,425° C., thus slightly above the melting point. Over time at this barely above melting point temperature, a solid, single silicon crystal grows within the molten silicon. A disposable quartz crystal is used to contain the silicon during single crystal formation, but large amounts of oxygen enter the molten silicon during the process. Dopants, often boron for forming P type and phosphorus for forming N type semiconductor material are added to the molten silicon in precise amounts to dope the silicon. Crystal formation is initiated when a seed crystal is dipped into the molten silicon and then slowly pulled upwards and rotated as it is pulled. The variables of temperature, pulling rate, and rotation provide the ability to extract a large, single-crystal, cylindrical, silicon ingot from the melt.

In both of these cases for making the desired wafer for use in solar cells, a single use crucible is required, oxygen and other contaminants are introduced, and wire sawing results in very low silicon yields (approximately 40% loss) while introducing physical cracks in the wafer requiring removal through etching. One prior attempt lacking some of these disadvantages used temperatures below the 1,414-degree Celsius melting point of the silicon by starting the process with much smaller silicon particles in the 220 nanometer (nm) to 10 micrometer (um) range. This method successfully sintered the silicon into a solid without melting the silicon, but was unsuccessful at producing high density objects as due to the lack of melting the density of the sintered solid approximated that of the pre-sintered powder.

As can be seen from the above description, there is an ongoing need for simple and efficient materials and methods for producing silicon suitable for use in solar cells that has the desired silicon density, while reducing the need for disposable crucibles, the loss of electrical performance from contaminants, and the loss of usable silicon material from wire sawing. The methods of present invention overcome at least one of the disadvantages associated with conventional devices.

### SUMMARY

In one aspect, the invention provides a method of forming polycrystalline silicon having a density of at least 95% by weight, the method including reducing the average diameter of at least four nines purity silicon to particles of 50 nanometers or less, the resulting reduced average diameter particles having at least 72 square meters of surface area per gram; sintering the resulting reduced average diameter particles from 1200 to 1400 degrees Celsius to form solid, the solid having from 10% to 25% less volume than the resulting reduced average diameter particles; and forming polycrystalline silicon.

Other methods, features and advantages of the invention will be, or will become, apparent to one with skill in the art upon examination of the following figures and description. It is intended that all such additional methods, features, and advantages be included within this description, be within the scope of the invention, and be protected by the claims that follow. The scope of the present invention is defined solely by the appended claims and is not affected by the statements within this summary.

### BRIEF DESCRIPTION OF THE FIGURES

The invention can be better understood with reference to the following drawings and description. The components in the figures are not necessarily to scale and are not intended to accurately represent molecules or their interactions, emphasis instead being placed upon illustrating the principles of the invention.

FIG. 1 represents a method of producing a polycrystalline silicon semiconductor material that may be used in solar cells.

FIG. 2 provides an image of the pellets obtained from the 1380-degree Celsius sintering.

FIG. 3 provides a graph comparing the density to surface area of 20 to 30±10% nanometer (nm) average diameter range particles.

### DETAILED DESCRIPTION

A method is described for the atmospheric pressure sintering of silicon to form high density polycrystalline silicon preforms that optionally may be annealed at higher temperatures to form wafers suitable for use in solar cells. The preforms are formed from nanometer scale, high surface area silicon that is sintered to form the near “full density” polycrystalline silicon preforms. Subsequent annealing of the preforms may be used to grow grains suitable for use as wafers for solar cells. The polycrystalline silicon may be used directly to form semiconductor structures other than wafers suitable for solar cells, such as to form electrodes, electrode surfaces, and thermoelectric devices.

Wafers resulting from the described method substantially reduce the high yield loss of silicon arising from oxygen contamination, wire sawing, and the associated etching. The described method uses classical ceramic engineering tools and techniques and much reduced capital and operating costs in relation to conventional techniques. Also, unlike in some methods, the starting material for the described process is high purity silicon, not silane.

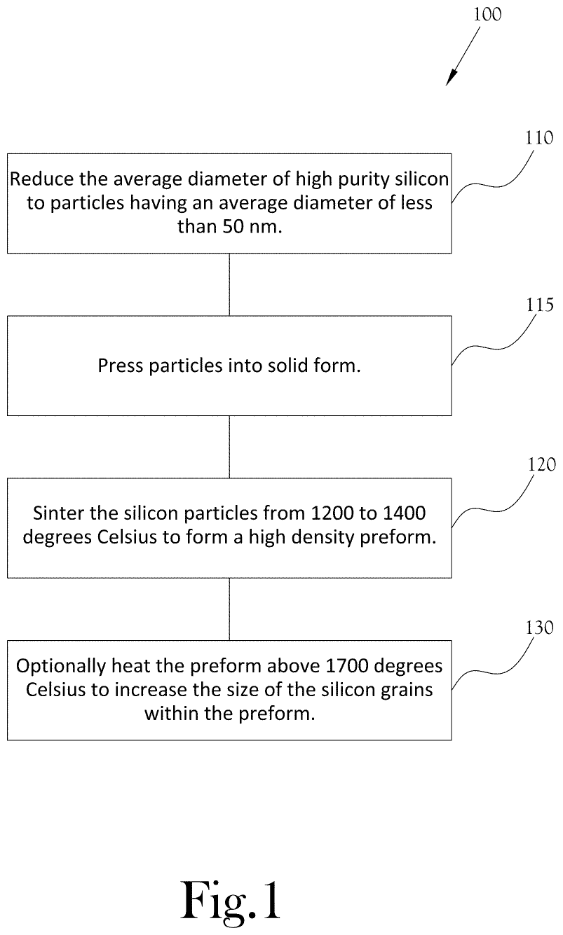

FIG. 1 represents a method 100 of producing a polycrystalline silicon semiconductor material that may be used in solar cells. The method 100 may be used to produce polycrystalline high-density silicon structures, polycrystalline high-density doped silicon structures, polycrystalline high-density silicon structures with annealing lengthened silicon grains, and polycrystalline high density doped silicon structures with annealing lengthened silicon grains.

In 110, the average diameter of high purity, at least “four-nines” (99.9999% pure) silicon is reduced to less than 50 nanometers (nm), preferably to the 20 to 30±10% nanometer (nm) average diameter range. While at least four-nines silicon may be used, at least six-nines silicon is preferred. Prior to reducing the average diameter of the silicon, the average diameter of the high purity silicon is preferably from 1 to 50 microns (um). Such high purity silicon of this type may be obtained from Ferro Globe in Spain, such as their 1.4-micron jet milled four nines pure silicon. The Ferro Globe silicon powder has a surface area of about 5.8 meters²/gram and an average particle diameter of just under 1.4-microns. Dopants of the n- or p-variety may optionally be included in the high purity silicon before or after the average diameter reduction.

The reduction of the larger high purity silicon particles to the less than 50 nm, preferably 20 to 30±10% nm average diameter range produces particles having at least 35 square meters of surface area per gram, preferably at least 50 square meters of surface area per gram, and more preferably at least 60 square meters of surface area per gram. Preferable particles have an average surface area per gram from 72 to 104 m²/g. More preferable particles have an average surface area per gram from 90 to 104 m²/g.

The reduction is preferably performed by milling the larger high purity silicon particles in an attrition mill under an ethanol cover liquid to exclude oxygen and other contaminants from the silicon during the milling process. An organic binder and/or lubricant/release agent also may be used during the milling process.

The outer shell of the resulting particles resulting from the reducing 110 is approximately 6 nm in depth. Thus, of a 20 nm average diameter silicon particle, approximately 12 nm of the average diameter, or 60% constitutes the outer shell. Similarly, for a 30 nm average diameter particle, approximately 12 nm of the average diameter, or 40% of the diameter constitutes the outer shell.

Thus, for the 20 nm diameter particle, the total volume of the shell is approximately 4,000 nm³, which provides an approximately 6% crystalline core by volume. A 30 nm diameter particle would have a total shell volume of approximately 11,000 nm³, which provides an approximately 22% crystalline core by volume. An 80 nm particle having the 6 nm shell would be approximately 61% crystalline. For comparison, a significantly larger 200 nm diameter particle would have a total shell volume of approximately 710,000 nm³, providing an approximately 83% crystalline core by volume. Thus, as the diameter of the particle increases, so does the percentage of the crystalline core as the thickness of the outer shell remains approximately the same.

Unlike the core of the particle, which is highly ordered crystalline silicon, the outer shell is amorphous silicon including silicon dioxide. Particles having crystalline cores from 10% to 30% by volume of the particle are preferred, and particles having crystalline cores from 15% to 25% by volume of the particle are more preferred.

In 115, the particles are pressed into a solid form after removal of the cover liquid. If an organic binder and/or lubricant/release agent are included, they are removed after the pressing. A combination of vacuum, heat, and purging with oxygen-containing or non-oxygen-containing gas may be used. Heating is below 1000 degrees Celsius, preferably from 100 to 500 degrees Celsius.

In 120, the silicon particle including solid form from the reducing 110 are sintered from 1200 degrees Celsius to 1400 degrees Celsius, preferably from 1280 degrees Celsius to 1390 degrees Celsius. Amorphous silicon melts below 1400 degrees Celsius, while crystalline silicon melts at approximately 1414 degrees Celsius. Thus, by heating to or near the melting point of the amorphous silicon, but below the melting point of the crystalline silicon, the amorphous silicon is believed to be converted to a liquid while the crystalline silicon is believed to remain a solid. This is believed to produce a liquid phase that is in substantially close contact with homogeneously dispersed solid, crystalline silicon “seeds”, thus permitting the formation of a nearly complete crystal structure throughout the silicon.

Sintering is continued until the particles lose from 10% to 25% of their initial volume, preferably from 15% to 22% of their initial volume. Sintering preferably is performed at approximately atmospheric pressure under argon. Depending on the sintering temperature selected, the sintering time may be altered to obtain the desired silicon density. Nitrogen may be introduced with the argon in the event a layer of silicon nitride is desired on the exterior surfaces of the pellets.

This volume reduction of the particles is believed to arise from the loss of impurities, mainly oxygen, and conversion of the amorphous material to crystalline silicon. The resultant high-density material has a silicon density of at least 95% by weight, preferably at least 98% by weight, and can achieve densities of 99.5% by weight. Silicon density may be determined by the Archimedes method where the mass of the silicon in and out of water is determined and compared.

In 130, the preform optionally may be heated to temperatures greater than 1700 degrees Celsius while substantially excluding oxygen. Once the polycrystalline silicon is formed at the low sintering temperature below the melting temperature of crystalline silicon, higher temperatures, including those above 1700 degrees Celsius, may be used to increase the size of the crystalline silicon grains within the material. Increasing the grain sizes is beneficial regarding the use of the polycrystalline silicon in solar cells, but may not be advantageous if the material formed in 120 is used as an electrode surface, for example.

Prior attempts at forming crystalline silicon at lower temperatures are believed to have been unsuccessful at producing structures of sufficient density because particles having an average diameter larger than 20 to 30±10% nm did not provide sufficient contact between the melted amorphous silicon and the solid crystalline “seed” silicon. Thus, the lack of a crystalline seed being present throughout the amorphous silicon during melting of the amorphous material permitted the melted amorphous material to undergo reactions other than forming crystalline material.

The following example illustrates one or more preferred embodiments of the invention. Numerous variations may be made to the following examples that lie within the scope of the invention.

### EXAMPLE

### Example 1

### Preparation of a High-Density Wafer

In one instance, four-nines silicon was obtained having an average diameter of approximately 1.4 microns for use as the starting material. In another instance, approximately 5-micron average diameter silicon derived from the decomposition of silane gas was used as the starting material.

An attrition mill was filled with approximately 500 grams of the starting material powder, 700 mL of ethanol, and approximately 2 to 3 liters of 3 mm silicon nitride ball milling media. The mill was operated at approximately 400 RPM until particles having an average diameter of 20 to 30±10% nm were obtained. The ethanol was extracted from the resulting nanometer scale particles and an organic binder was added. A preferable organic binder is polyacrylic acid; however, other organic binders that are compatible with formation of the high-density polycrystalline silicon may be used. Steric acid also was added as a lubricant and release agent.

The resulting material was then pressed into pellets of either 12 or 25 millimeters (mm) in diameter and approximately 500 ums thick. Pressures from 10 to 140 MPa were used to form the pellets.

The pellets were then subjected to an approximately 180-degree Celsius temperature under vacuum to remove the stearic acid and then air introduced to remove the binder.

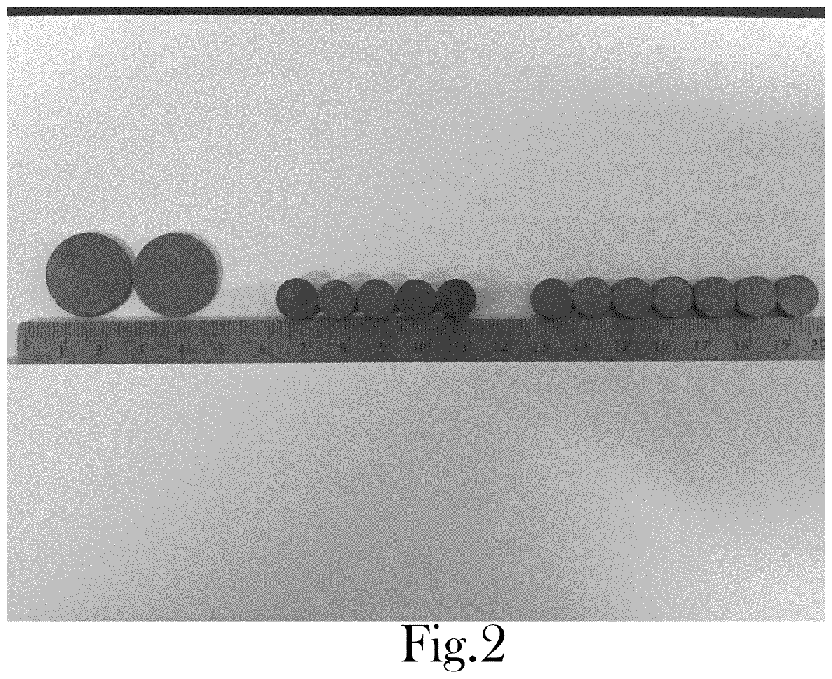

The pellets were then placed under vacuum and then brought up to approximately atmospheric pressure with argon. The pellets were then sintered from approximately 1280 degrees Celsius to 1400 degrees Celsius at approximately atmospheric pressure under the argon atmosphere. In another instance, the pellets were sintered at 1380 degrees Celsius under the argon atmosphere for approximately 1 hour. FIG. 2 provides an image of the pellets obtained from the 1380-degree Celsius sintering.

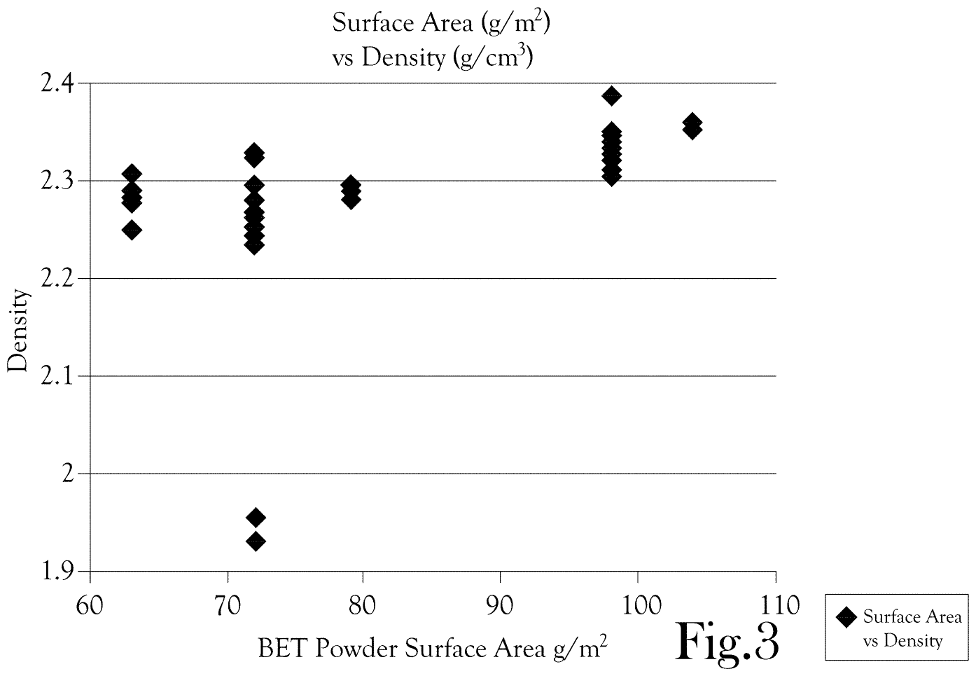

This process produced pellets of high-density silicon having a silicon density of at least 98% by weight, and in most instances at least 99% by weight. As shown by the graph in FIG. 3, silicon particles having surface areas in excess of 60 g/m² up to approximately 105 g/m² were used to form the high-density pellets. Once formed, the high-density pellets may be further annealed at high temperature, thus above 1700 degrees Celsius to promote the growth of larger polycrystalline grains within the pellets.

Unless the context clearly dictates otherwise, where a range of values is provided, each intervening value to the tenth of the unit of the lower limit between the lower limit and the upper limit of the range is included in the range of values.

While various aspects of the invention are described, it will be apparent to those of ordinary skill in the art that other embodiments and implementations are possible within the scope of the invention. Accordingly, the invention is not to be restricted except in light of the attached claims and their equivalents.

1. A method of forming polycrystalline silicon having a density of at least 95% by weight, the method comprising:
reducing the average diameter of at least four nines purity silicon to particles of 50 nanometers or less, the resulting reduced average diameter particles having at least 72 square meters of surface area per gram;
sintering the resulting reduced average diameter particles from 1200 to 1400 degrees Celsius to form solid, the solid having from 10% to 25% less volume than the resulting reduced average diameter particles; and
forming polycrystalline silicon.

2. The method of claim 1, where the average diameter of the at least four nines purity silicon is from 1 to 50 microns.

3. The method of claim 1, where the resulting reduced average diameter particles have from 72 to 104 square meters of surface area per gram.

4. The method of claim 1, where the resulting reduced average diameter particles have from 90 to 104 square meters of surface area per gram.

5. The method of claim 1, where the reducing is performed in an attrition mill under an ethanol cover.

6. The method of claim 1, the solid having from 15% to 22% less volume than the resulting reduced average diameter particles.

7. The method of claim 1, where the sintering for the resulting reduced average diameter particles is from 1280 to 1390 degrees Celsius.

8. The method of claim 1, further comprising prior to the sintering combining the resulting reduced average diameter particles with a binder and pressing the combination into pellets.

9. The method of claim 8, further comprising prior to the sintering removing the binder from the pellets at approximately 100 to 500 degrees Celsius.

10. The method of claim 1, where the sintering is at approximately atmospheric pressure under an argon atmosphere.

11. The method of claim 10, where the argon atmosphere further comprises nitrogen.

12. The method of claim 1, further comprising annealing the polycrystalline silicon at temperatures above 1700 degrees Celsius after forming the polycrystalline silicon.

13. The method of claim 1, where the resulting reduced average diameter particles are from 10% to 30% crystalline silicon by volume.

14. The method of claim 1, where the resulting reduced average diameter particles are from 15% to 25% crystalline silicon by volume.
